(19) United States
(12) Patent Application Publication
(10) Pub. No.: US 2026/0163400 A1
(43) Pub. Date: Jun. 11, 2026

(54) Hybrid Transfer Switch for High Reliability for High Reliability and Reduced Transfer Times

(71) Applicant: ABB Schweiz AG, Baden (CH)

(72) Inventors: Govind S. Chavan, Garner, NC (US); Zhou Dong, Raleigh, NC (US)

(73) Assignee: ABB Schweiz AG, Baden (CH)

(21) Appl. No.: 18/975,304

(22) Filed: Dec. 10, 2024

(51) Int. Cl. H02J 9/06; H03K 17/56

(52) U.S. Cl. CPC H02J 9/068; H02J 9/062; H03K 17/56

(57) ABSTRACT

A system for executing a transfer from a first power source to a second power source is provided. The system includes one or more sensors configured to detect an electrical measurement associated with powering a load and a controller. The controller disconnects the first power source from the load, initiates a first connection between the second power source and the load via a mechanical switch and a second connection between the second power source and the load via a semiconductor switch assembly, based on determining that a current from the first power source is reduced to zero, and disconnects the second connection between the second power source and the load via the semiconductor switch assembly based on determining that the first connection between the second power source and the load via the mechanical switch is established.

### FIELD

The invention relates to a switching arrangement, a system and a method for load transfer of supply voltage.

### BACKGROUND

Automatic Transfer Switches (ATS) are widely used in AC power distribution systems to provide reliable power to critical applications by switching between a preferred power source and a backup source. The typical operation of an ATS involves electromechanical switches, which take time to transition between on and off states, leading to transfer delays ranging from tens to hundreds of milliseconds. While these delays are tolerable in non-critical applications, they can be problematic in sensitive environments such as hospitals or industrial systems. A faster solution, the Static Transfer Switch (STS), which uses semiconductor switches like silicon-controlled rectifiers (SCRs), offers much quicker transfer times (under 20 milliseconds). However, STS systems are significantly more expensive due to the need for continuous heat dissipation and robust components to handle high currents.

To improve efficiency, WO2018157915A1 proposes combining a fast mechanical commutating switch (FCS) in parallel with semiconductors in the STS. This hybrid solution reduces conduction losses, but it remains costly due to the expensive FCS components and the need for semiconductors to handle short-circuit currents. While this system is more efficient than traditional STS setups, it is not cost-effective compared to ATS systems.

### SUMMARY

A first aspect of the present disclosure provides a system for executing a transfer from a first power source to a second power source, the system comprising: one or more sensors configured to detect an electrical measurement associated with powering a load; and a controller configured to: disconnect the first power source from the load; initiate a first connection between the second power source and the load via a mechanical switch and a second connection between the second power source and the load via a semiconductor switch assembly, based on determining that a current from the first power source is reduced to zero; disconnect the second connection between the second power source and the load via the semiconductor switch assembly based on determining that the first connection between the second power source and the load via the mechanical switch is established.

According to an implementation of the first aspect, the first connection and the second connection between the second power source and the load are in parallel.

According to an implementation of the first aspect, the semiconductor switch assembly comprises at least one of silicon-controlled rectifiers (SCRs), insulate gate bipolar transistors (IGBTs), metal-oxide-semiconductors (MOSFETs), integrated gate-commutated thyristors (IGCTs), and gate turn-off thyristors (GTOs).

According to an implementation of the first aspect, the first connection between the second power source and the load via the mechanical switch is completed in a first time period, the second connection between the second power source and the load via the semiconductor switch assembly is competed in a second time period, and the second period is less than the first time period.

According to an implementation of the first aspect, the second connection between the second power source and the load via the semiconductor switch assembly is disconnected further based on determining that current flowing through the semiconductor switch assembly is below a predetermined threshold.

According to an implementation of the first aspect, the system further comprises a transformer electrically coupled to a load, wherein the first power source and the second power source are configured to provide power to the load via the transformer.

According to an implementation of the first aspect, the controller is further configured to: determine a load transformer flux based on a voltage of the first power source at a time when the first power source is disconnected from the load; determine a resultant transformer flux based on a voltage of the second power source; and initiate the first connection and the second connection based on determining that the resultant transformer flux is similar to the load transformer flux.

According to an implementation of the first aspect, the first power source is disconnected from the load based on determining that the current provided by the first power source to the load is approximately zero.

A second aspect of the present disclosure provides a method for executing a transfer from a first power source to a second power source, the method comprising: disconnecting the first power source from the load; initiating a first connection between the second power source and a load via a mechanical switch and a second connection between the second power source and the load via a semiconductor switch assembly, based on determining that a current from the first power source is reduced to zero; disconnecting the second connection between the second power source and the load via the semiconductor switch assembly based on determining that the first connection between the second power source and the load via the mechanical switch is established.

### BRIEF DESCRIPTION OF DRAWINGS

Embodiments of the present disclosure will be described in even greater detail below based on the exemplary figures. The present disclosure is not limited to the exemplary embodiments. All features described and/or illustrated herein can be used alone or combined in different combinations in embodiments of the present disclosure. The features and advantages of various embodiments of the present disclosure will become apparent by reading the following detailed description with reference to the attached drawings which illustrate the following:

FIG. 1 is a simplified block diagram depicting an exemplary hybrid switch, in accordance with one or more examples of the present application.

FIG. 2 is a simplified circuit diagram depicting the exemplary hybrid switching system, in accordance with one or more examples of the present application.

FIG. 3 is a simplified block diagram of one or more devices or systems within the exemplary environment of FIG. 1.

FIG. 4 illustrates an exemplary process to switch powering a load from a first power source to a second power source using a hybrid transfer switch, according to one or more examples of the present disclosure.

### DETAILED DESCRIPTION

Examples of the presented application will now be described more fully hereinafter with reference to the accompanying FIGs., in which some, but not all, examples of the application are shown. Indeed, the application may be exemplified in different forms and should not be construed as limited to the examples set forth herein; rather, these examples are provided so that the application will satisfy applicable legal requirements. Where possible, any terms expressed in the singular form herein are meant to also include the plural form and vice versa, unless explicitly stated otherwise. Also, as used herein, the term “a” and/or “an” shall mean “one or more” even though the phrase “one or more” is also used herein. Furthermore, when it is said herein that something is “based on” something else, it may be based on one or more other things as well. In other words, unless expressly indicated otherwise, as used herein “based on” means “based at least in part on” or “based at least partially on”.

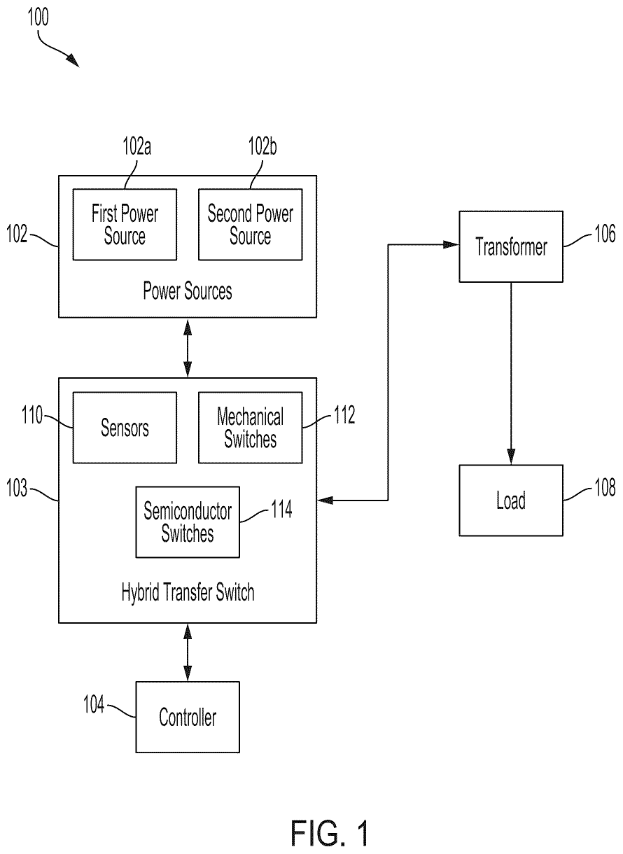

Systems, methods, and computer program products are herein disclosed that provide for hybrid transfer switches (ATS) that execute swift transfer between powering a load using a first power source and a second power source. FIG. 1 is a simplified block diagram depicting an exemplary hybrid transfer switch in an automatic switching environment 100, in accordance with one or more examples of the present application. FIG. 1 includes power sources 102, a hybrid transfer switch 103, a controller 104, a transformer 106, and a load 108. Power sources 102 may include a first power source 102a and a second power source 102b. The power sources 102 may provide power to power one or more loads such as load 108. For example, the first power source 102a may provide power to the load 108. After a certain amount of time, the first power source 102a may be disconnected from the load 108, and instead, the second power source 102b may be connected to the load 108. In some examples, the first power source 102a may be a primary source and the second power source 102b may be a backup or a secondary power source. In some variations, the first power source 102a and the second power source 102b may be alternating current (AC) power sources that provide alternating current/power to the load 108. In some variations, the first power source 102a and the second power source 102b may be single phase or three phase power sources.

The load 108 may be any type of load that uses power from the power sources 102 to perform one or more tasks. In some embodiments, the load 108 may accept AC power and/or direct current (DC) power from the power sources 102 via the transformer 106. The transformer 106 may be a device that transfers electrical energy from one circuit to another circuit (e.g., from the power sources 102 to the load 108). In some instances, the transformer 106 may convert and/or otherwise alter the current, voltage, and/or power from the power sources 102 prior to providing the current, voltage, and/or power to the load 108. For instance, the transformer 106 may step up and/or step down the current from the power sources 102 prior to providing the current to the load 108.

The controller 104 is in electrical communication with one or more components of the hybrid transfer switch 103. Additionally, and/or alternatively, while not shown, the controller 104 may also be in communication with other components within the environment 100 including the power sources 102, the transformer 106, and/or the load 108. For instance, the controller 104 may be in communication with the transformer 106 and/or one or more sensors associated with the transformer 106 to determine the status of the transformer 106. The controller 104 may be any type of hardware and/or software logic, such as a central processing unit (CPU), RASPBERRY PI processor/logic, processor, and/or logic, that executes computer executable instructions for performing the functions, processes, and/or methods described herein.

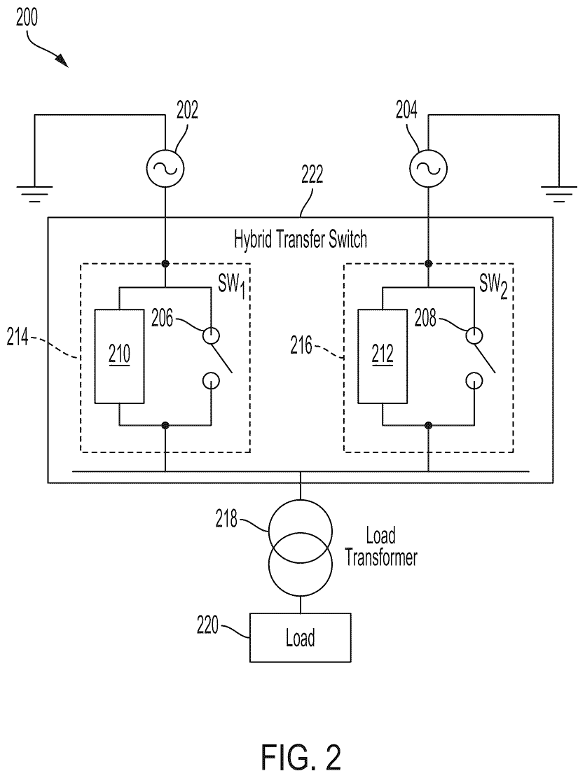

The hybrid transfer switch 103 may include one or more sensors 110, one or more mechanical switches 112, and one or more semiconductor switches 114, which may be described in FIG. 2 below. The controller 104 may use one or more components of the hybrid transfer switch 103 to swiftly switch between powering the load 108 using the first power source 102a and powering the load 108 using the second power source 102b, based on measurements obtained from the sensors 110 of the hybrid transfer switch 103. Additionally, and/or alternatively, in some embodiments, an external input may be used to switch between powering the load 108 using the first power source 102a and powering the load 108 using the second power source 102b. In such embodiments, the external input may be provided to the controller 104 to initiate the switch between powering the load 108 using the first power source 102a and powering the load 108 using the second power source 102b.

The sensors 110 may include current sensors, voltage sensors, and/or other sensors that provide measurements (e.g., current measurements) to the controller 104. The mechanical switches 112 (e.g., an electromechanical switch) may be any type of physical switch with mechanical moving parts. The semiconductor switches 114 may be any type of semiconductor switching devices (e.g., silicon controlled rectifiers (SCRs), solid state switchers, or other semiconductor switches, Gate turn-off (GTO) thyristors, Integrated gate-commutated thyristors (IGCTs), Insulated gate bipolar transistors (IGBTs), Metal-oxide-semiconductor field effect transistors (MOSFETs)). These semiconductor switches may have forced commutation circuits that allow current interruption at instances other than a zero current crossing. In some embodiments, the semiconductor switch is a four-quadrant switch, i.e., it is capable of blocking voltages of both polarities and capable of carrying current in both directions.

The combination of mechanical switches 112 and the semiconductor switches 114 are configured to swiftly switch between powering the load 108 using the first power source 102a and the second power source 102b. For instance, the controller 104 may use the mechanical switches 112 to and the semiconductor switches 114 to switch between powering the load 108 using the first power source 102a to powering the load 108 using the second power source 102b, and vice versa.

In some examples, the controller 104 may switch how the load 108 is being powered based on one or more factors. For instance, initially, the load 108 may be powered by the first power source 102a. Based on the one or more factors, the controller 104 may switch from powering the load 108 using the first power source 102a to powering the load 108 using the second power source 102b. After a certain amount of time has elapsed, the controller 104 may switch back and power the load 108 using the first power source 102a. These factors may include, but are not limited to, sudden increase or decrease of voltage of the first AC power source 102a, sudden increase or decrease of the frequency of the first power source 102a, inability by the first AC power source 102a to provide the necessary power required by load 108, and failure of the first AC power source 102a. In some examples, the controller 104 may be configured to routinely transfer between using the first power source 102a and the second power source 102b for powering the load 108. In such examples, hybrid transfer switches 103 may switch between the first power source 102a and second power source 102b occasionally and/or periodically at regular intervals of time.

In order to swiftly execute the transfer from the first power source 102a to the second power source 102b, the mechanical switches 112 and the semiconductor switches 114 are connected in parallel between the power sources 102 and the load 108. For example, a first mechanical switch of the mechanical switches 112 may establish a connection between the first power source 102a and the load 108. Simultaneously, a first semiconductor switch of the semiconductor switches 114 may establish a second connection between the first power source 102a and the load 108. The first mechanical switch and the first semiconductor switch that establish a connection between the first power source 102a and the load 108 are in parallel.

Similarly, a second mechanical switch of the mechanical switches 112 may establish a connection between the second power source 102b and the load 108. A second semiconductor switch of the semiconductor switches 114 may establish a second connection between the second power source 102b and the load 108. The second mechanical switch and the second semiconductor switch that establish a connection between the second power source 102b and the load 108 are in parallel.

In some embodiments, the controller 104 may determine that the first power source 102a is unable to supply power to the load 108. For example, the controller 104 may determine a sudden increase or decrease of voltage of the first AC power source 102a, sudden increase or decrease of the frequency of the first power source 102a, inability by the first AC power source 102a to provide the necessary power required by load 108, or failure of the first AC power source 102a. In such cases, the controller 104 may instruct the hybrid transfer switch 103 to disconnect the first power source 102a from the load 108. The hybrid transfer switch 103 may disconnect first mechanical switch of the mechanical switches 112 from the first power source, thereby severing the connection between the first power source 102a and the load 108. The process of disconnecting the first mechanical switch to sever the connection between the first power source 102a and the load 108 may take t_{off} milliseconds to complete.

Once the first power source 103 is disconnected from the load 108, the current from the first power source 102a to the load 108 reduces to zero. When the controller 104, using sensors 110, determines that the current from the first power source 102a to the load 108 is close to zero, the controller 104 instructs the hybrid transfer switch 103 to initiate connections between the second power source 102b and the load 108 using a second mechanical switch of the mechanical switches 112 and a second semiconductor switch of the semiconductor switches 114. As described above, the second mechanical switch of the mechanical switches 112 and the second semiconductor switch of the semiconductor switches 114 are connected in parallel.

The second semiconductor switch of the semiconductor switches 114 is able to form a connection between the second power source 102b and the load 108 in t_{semiconductor} microseconds. Current between the second power source 102b and the load 108 starts flowing almost instantly.

In the meantime, the second mechanical switch of the mechanical switches 112 completes the connection between the second power source 102b and the load 108. The second mechanical switch of the mechanical switches 112 takes about tₒₙ milliseconds to close.

Once the second mechanical switch of the mechanical switches 112 is closed, the connection between the second power source 102b and the load is completed using both the second semiconductor switch of the semiconductor switches 114 and the second mechanical switch of the mechanical switches 112. As the on-state resistance of the second mechanical switch of the mechanical switches 112 is significantly lower than that of the second semiconductor switch of the semiconductor switches 114, once the second mechanical switch closes, most of the current between the second power source 102b and the load 108 is diverted towards the second mechanical switch.

In some embodiments, the sensors 110 of the hybrid transfer switch 103 monitor a reduction in current in the second semiconductor switch using a current sensor. In some cases, a reduction in voltage across the second semiconductor switch may be monitored using a voltage sensor of the sensors 110. The reduction in current or voltage, as measured by the sensors 110 is provided as feedback to the controller 104. In response to the feedback received from the hybrid transfer switch 103, the controller 104 may instruct the hybrid transfer switch 103 to disconnect the second semiconductor switch of the semiconductor switches 114, such that all the current from the second power source 102b to the load 108 flows through the second mechanical switch of the mechanical switches 112.

Therefore, the total time to transfer from the first power source 102a to the second power source 102b can be expressed as:

$${t}_{transfer} \geq {t}_{off} + {t}_{semiconductor} \approx {t}_{off}$$

As the t_{off} is orders of magnitude greater than t_{semiconductor}, t_{transfer} may be approximated as t_{off}, which is the time taken to completely disconnect the load 108 from the first power source 102a by disconnecting the first mechanical switch.

A similar transfer process may occur when transferring power from the second power source 102b to the first power source 102a.

FIG. 2 is a simplified circuit diagram depicting the exemplary automatic switching system in accordance with one or more examples of the present application.

The circuit diagram 200 shown in FIG. 2 depicts a first power source 202 and a second power source 204. The first power source 202 of FIG. 2 is similar to the first power source 102a as shown in FIG. 1. The second power source 204 of FIG. 2 is similar to the second power source 102b as shown in FIG. 1. The first power source 202 and the second power source 204 are configured to supply power to the load 220 via a hybrid power source 222. In some embodiments, the first power source 202 is connected to the load 220 using a first portion of the first hybrid transfer switch 214. The first portion of the hybrid transfer switch 214 includes a first mechanical switch 206 and a first semiconductor switch 210 connected in parallel.

Similarly, the second power source 204 is connected to the load 220 using a second portion of the hybrid transfer switch 216. The second portion of the hybrid transfer switch 216 includes a second mechanical switch 208 and a second semiconductor switch 212 connected in parallel. The first mechanical switch 206 and the second mechanical switch 208 are similar to the mechanical switches 112 as described in FIG. 1. The first semiconductor switch 210 and the second semiconductor switch 212 are similar to the semiconductor switches 114 as described in FIG. 1.

During normal operation, the first power source 202 is connected to the load 220 via the first mechanical switch 206. In such a case, the first mechanical switch 206 is closed, while the second mechanical switch 206, the first semiconductor switch 210, and the second semiconductor switch 212 are open. Upon detecting that the first power source 202 is unable to continue supplying power to the load 220, the controller 104 may instruct the hybrid transfer switch 222 to disconnect the first power source 202 from the load 220 by opening the first mechanical switch 206.

Once the controller 104, based on measurements provided by a current sensor associated with the first power source 202, determines that the current from the first power source 202 has reduced to approximately zero, the controller 104 instructs the hybrid switch 222 to close the second mechanical switch 208 and the second semiconductor switch 212 to establish a connection between the second power source 204 and the load 220. As described above, the second mechanical switch of the mechanical switches 112 and the second semiconductor switch of the semiconductor switches 114 are connected in parallel.

The second semiconductor switch 212 is able to form a connection between the second power source 204 and the load 220 in t_{off} microseconds. Current between the second power source 204 and the load 220 starts flowing almost instantly.

In the meantime, the second mechanical switch 208 completes the connection between the second power source 204 and the load 220. The second mechanical switch 208 takes about tₒₙ milliseconds to close.

Once the second mechanical switch 208 is closed, the connection between the second power source 204 and the load 220 is completed using both the second semiconductor switch 212 and the second mechanical switch 208. As the on-state resistance of the second mechanical switch 208 is significantly lower than that of the second semiconductor switch 212, once the second mechanical switch 208 closes, most of the current between the second power source 204 and the load 220 is diverted towards the second mechanical switch 208.

In some embodiments, the sensors of the hybrid transfer switch 222 monitor a reduction in current in the second semiconductor switch 212 using a current sensor. In some cases, a reduction in voltage across the second semiconductor switch 212 may be monitored using a voltage sensor of the sensors. In such cases, a reduction in voltage across the second semiconductor switch 212 may be an indication that the current through the semiconductor switch 212 is below a predetermined threshold. The reduction in current or voltage, as measured by the sensors is provided as feedback to the controller 104. In response to the feedback received from the hybrid transfer switch 222, the controller 104 may instruct the hybrid transfer switch 222 to disconnect the second semiconductor switch 212, such that all the current from the second power source 204 to the load 220 flows through the second mechanical switch 208. For example, upon determining that the current through the semiconductor switch 212 is below a predetermined threshold, the controller 104 may instruct the hybrid transfer switch 222 to disconnect the second semiconductor switch 212. Additionally, and/or alternatively, upon determining that the voltage across the semiconductor switch 212 as measured by the voltage sensor of the sensors is below a predetermined threshold, the controller 104 may instruct the hybrid transfer switch 222 to disconnect the second semiconductor switch 212.

A similar transfer process may occur when transferring power from the second power source 204 to the first power source 202.

In some embodiments, there may be a load transformer 218 downstream of the hybrid transfer switch 222. The controller 104 of the hybrid transfer switch 218 may control inrush current that flows from the second power source 204 during the transfer from the first power source 202 to the second power source 204. In order to perform the transfer from the first power source 202 to the second power source 204, the controller 104 estimates a load transformer flux from a voltage of the first power source 202 till the load current from the first power source 202 drops to zero. At this point, the controller 104 instructs the hybrid transfer switch 222 to disconnect the load transformer 218 from the first power source 202, and the transformer flux becomes locked at this value. The controller 104 also measures voltage and estimates the resultant transformer flux based on voltage of the second power source 204. When the estimated transformer flux of the second power source 204 equals the locked transformer flux after the disconnection from first power source, the controller 104 instructs the hybrid transfer switch 222 to connect the second semiconductor switch 212 and the second mechanical switch 208, completing the transfer process. This algorithm may add up to 20 milliseconds to the transfer time.

In some embodiments, in case the second semiconductor switch 204 is closed to eliminate the arc of the second mechanical switch 208 and shut down the current, the second mechanical switch 208 may be chosen to have a lower current interruption capability, which results in further savings of resources.

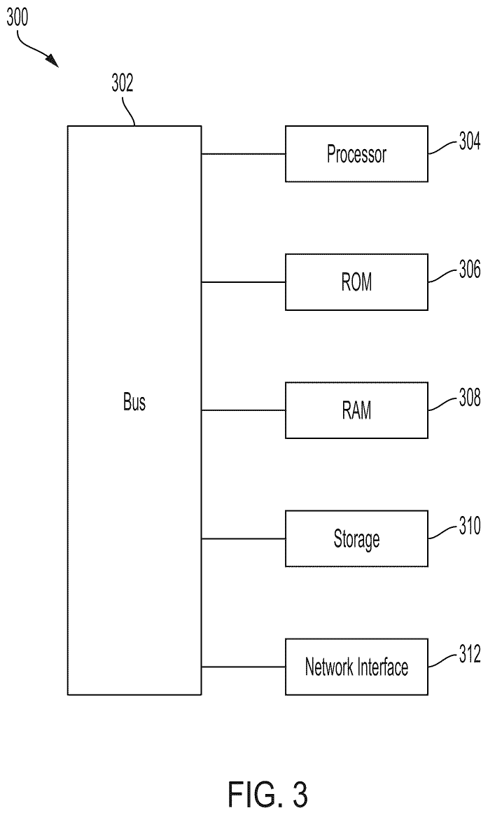

FIG. 3 is a block diagram of an exemplary system or device 300 within the environment 100 such as the controller 104. The system 300 includes a processor 304, such as a central processing unit (CPU), and/or logic, that executes computer executable instructions for performing the functions, processes, and/or methods described herein. In some examples, the computer executable instructions are locally stored and accessed from a non-transitory computer readable medium, such as storage 310, which may be a hard drive or flash drive. Read Only Memory (ROM) 306 includes computer executable instructions for initializing the processor 304, while the random-access memory (RAM) 308 is the main memory for loading and processing instructions executed by the processor 304. The network interface 312 may connect to a wired network or cellular network and to a local area network or wide area network. The system 300 may also include a bus 302 that connects the processor 304, ROM 306, RAM 308, storage 310, and/or the network interface 312. The components within the system 300 may use the bus 302 to communicate with each other. The components within the system 300 are merely exemplary and might not be inclusive of every component within the controller 104. Additionally, and/or alternatively, the system 300 may further include components that might not be included within every entity of environment 100. For instance, in some examples, the controller 104 might not include a network interface 312.

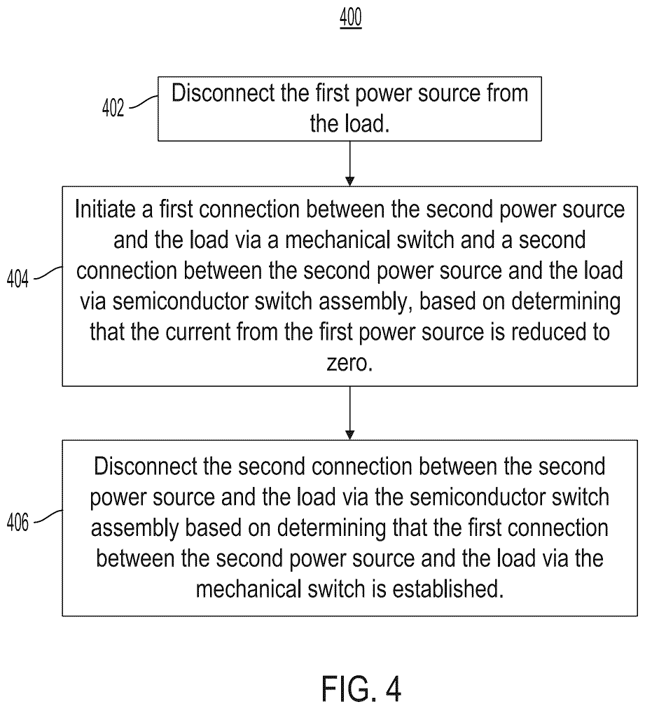

FIG. 4 illustrates an exemplary process to switch powering a load from a first power source to a second power source using a hybrid transfer switch, according to one or more examples of the present disclosure. In some embodiments, the process 400 may be performed by the environment 100 of FIG. 1 such as the controller 104. However, it will be recognized that any of the following blocks may be performed in any suitable order and that the process 400 may be performed in any environment and by any suitable computing device and/or controller. For instance, the process 400 may also be performed by the controller 104 shown in FIG. 1.

At 402, the first power source is disconnected from the load. In some embodiments, a first power source 102a may be disconnected from the load 108 based on a plurality of factors. These factors may include, but are not limited to, a sudden increase or decrease of voltage of the first AC power source 102a, sudden increase or decrease of the frequency of the first power source 102a, inability by the first AC power source 102a to provide the necessary power required by load 108, and failure of the first AC power source 102a. In some examples, the controller 104 may be configured to routinely transfer between using the first power source 102a and the second power source 102b for powering the load 108. In such examples, hybrid transfer switches 103 may switch between the first power source 102a and second power source 102b occasionally and/or periodically at regular intervals of time.

At 404, the controller 104 initiates a first connection between the second power source and the load via a mechanical switch and a second connection between the second power source and the load via semiconductor switch assembly, based on determining that the current from the first power source is reduced to zero. In some embodiments, the controller 104 may instruct the hybrid transfer switch 103 to disconnect the first power source 102a from the load 108. The hybrid transfer switch 103 may disconnect first mechanical switch of the mechanical switches 112 from the first power source, thereby severing the connection between the first power source 102a and the load 108. The process of disconnecting the first mechanical switch to sever the connection between the first power source 102a and the load 108 may take t_{off} milliseconds to complete. Once the first power source 102a is disconnected from the load 108, the current from the first power source 102a to the load 108 reduces to zero. When the controller 104, using sensors 110, determines that the current from the first power source 102a to the load 108 is close to zero, the controller 104 instructs the hybrid transfer switch 103 to initiate connections between the second power source 102b and the load 108 using a second mechanical switch of the mechanical switches 112 and a second semiconductor switch of the semiconductor switches 114. In some embodiments, the second semiconductor switch of the semiconductor switches 114 is able to form a connection between the second power source 102b and the load 108 in t_{semiconductor} microseconds. Current between the second power source 102b and the load 108 starts flowing almost instantly. In the meantime, the second mechanical switch of the mechanical switches 112 completes the connection between the second power source 102b and the load 108. The second mechanical switch of the mechanical switches 112 takes about tₒₙ milliseconds to close.

At 406, the controller 104 disconnects the second connection between the second power source and the load via the semiconductor switch assembly based on determining that the first connection between the second power source and the load via the mechanical switch is established. In some embodiments, once the second mechanical switch of the mechanical switches 112 is closed, the connection between the second power source 102b and the load is completed using both the second semiconductor switch of the semiconductor switches 114 and the second mechanical switch of the mechanical switches 112. As the on-state resistance of the second mechanical switch of the mechanical switches 112 is significantly lower than that of the second semiconductor switch of the semiconductor switches 114, once the second mechanical switch closes, most of the current between the second power source 102b and the load 108 is diverted towards the second mechanical switch. In some cases, a reduction in voltage across the second semiconductor switch may be monitored using a voltage sensor of the sensors 110. The reduction in current or voltage, as measured by the sensors 110 is provided as feedback to the controller 104. In response to the feedback received from the hybrid transfer switch 103, the controller 104 may instruct the hybrid transfer switch 103 to disconnect the second semiconductor switch of the semiconductor switches 114, such that all the current from the second power source 102b to the load 108 flows through the second mechanical switch of the mechanical switches 112.

While embodiments of the invention have been illustrated and described in detail in the drawings and foregoing description, such illustration and description are to be considered illustrative or exemplary and not restrictive. It will be understood that changes and modifications may be made by those of ordinary skill within the scope of the following claims. In particular, the present invention covers further embodiments with any combination of features from different embodiments described above and below. For example, the various embodiments of the kinematic, control, electrical, mounting, and user interface subsystems can be used interchangeably without departing from the scope of the invention. Additionally, statements made herein characterizing the invention refer to an embodiment of the invention and not necessarily all embodiments.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

1. A system for executing a transfer from a first power source to a second power source, the system comprising:
one or more sensors configured to detect an electrical measurement associated with powering a load; and
a controller configured to:
disconnect the first power source from the load;
initiate a first connection between the second power source and the load via a mechanical switch and a second connection between the second power source and the load via a semiconductor switch assembly, based on determining that a current from the first power source is reduced to zero; and
disconnect the second connection between the second power source and the load via the semiconductor switch assembly based on determining that the first connection between the second power source and the load via the mechanical switch is established.

2. The system of claim 1, wherein the first connection and the second connection between the second power source and the load are in parallel.

3. The system of claim 1, wherein the semiconductor switch assembly comprises at least one of silicon-controlled rectifiers (SCRs), insulate gate bipolar transistors (IGBTs), metal-oxide-semiconductors (MOSFETs), integrated gate-commutated thyristors (IGCTs), and gate turn-off thyristors (GTOs).

4. The system of claim 1, wherein:
the first connection between the second power source and the load via the mechanical switch is completed in a first time period,
the second connection between the second power source and the load via the semiconductor switch assembly is competed in a second time period, and
the second period is less than the first time period.

5. The system of claim 1, wherein the second connection between the second power source and the load via the semiconductor switch assembly is disconnected further based on determining that current flowing through the semiconductor switch assembly is below a predetermined threshold.

6. The system of claim 1, further comprising a transformer electrically coupled to a load, wherein the first power source and the second power source are configured to provide power to the load via the transformer.

7. The system of claim 6, wherein the controller is further configured to:
determine a load transformer flux based on a voltage of the first power source at a time when the first power source is disconnected from the load;
determine a resultant transformer flux based on a voltage of the second power source; and
initiate the first connection and the second connection based on determining that the resultant transformer flux is similar to the load transformer flux.

8. The system of claim 1, wherein the first power source is disconnected from the load based on determining that the current provided by the first power source to the load is approximately zero.

9. A method for executing a transfer from a first power source to a second power source, the method comprising:
disconnecting the first power source from the load;
initiating a first connection between the second power source and a load via a mechanical switch and a second connection between the second power source and the load via a semiconductor switch assembly, based on determining that a current from the first power source is reduced to zero; and
disconnecting the second connection between the second power source and the load via the semiconductor switch assembly based on determining that the first connection between the second power source and the load via the mechanical switch is established.

10. The method of claim 9, wherein the first connection and the second connection between the second power source and the load are in parallel.

11. The method of claim 9, wherein the semiconductor switch assembly comprises at least one of silicon-controlled rectifiers (SCRs), insulate gate bipolar transistors (IGBTs), metal-oxide-semiconductors (MOSFETs), integrated gate-commutated thyristors (IGCTs), and gate turn-off thyristors (GTOs).

12. The method of claim 9, wherein:
the first connection between the second power source and the load via the mechanical switch is completed in a first time period,
the second connection between the second power source and the load via the semiconductor switch assembly is competed in a second time period, and
the second period is less than the first time period.

13. The method of claim 9, wherein the second connection between the second power source and the load via the semiconductor switch assembly is disconnected further based on determining that current flowing through the semiconductor switch assembly is below a predetermined threshold.

14. The method of claim 9, wherein the second connection between the second power source and the load via the semiconductor switch assembly is disconnected further based on determining that a voltage measured across the semiconductor switch assembly is below a predetermined threshold.

15. The method of claim 9, further comprising a transformer electrically coupled to a load, wherein the first power source and the second power source are configured to provide power to the load via the transformer.

16. The method of claim 15, wherein the method further comprises:
determining a load transformer flux based on a voltage of the first power source at a time when the first power source is disconnected from the load;
determining a resultant transformer flux based on a voltage of the second power source; and
initiating the first connection and the second connection based on determining that the resultant transformer flux is similar to the load transformer flux.

17. A tangible, non-transitory computer-readable medium for executing a transfer from a first power source to a second power source, the computer-readable medium having instructions thereon, which, upon being executed by one or more processors, provides for execution of the following steps:
disconnecting the first power source from the load;
initiating a first connection between the second power source and a load via a mechanical switch and a second connection between the second power source and the load via a semiconductor switch assembly, based on determining that a current from the first power source is reduced to zero; and
disconnecting the second connection between the second power source and the load via the semiconductor switch assembly based on determining that the first connection between the second power source and the load via the mechanical switch is established.

18. The non-transitory computer-readable medium of claim 17, wherein the first connection and the second connection between the second power source and the load are in parallel.

19. The non-transitory computer-readable medium of claim 17, wherein the semiconductor switch assembly comprises at least one of silicon-controlled rectifiers (SCRs),
insulate gate bipolar transistors (IGBTs), metal-oxide-semiconductors (MOSFETs), integrated gate-commutated thyristors (IGCTs), and gate turn-off thyristors (GTOs).

20. The non-transitory computer-readable medium of claim 17, wherein:
the first connection between the second power source and the load via the mechanical switch is completed in a first time period,
the second connection between the second power source and the load via the semiconductor switch assembly is competed in a second time period, and
the second period is less than the first time period.
